(19) United States
(12) Patent Application Publication
(10) Pub. No.: US 2024/0053843 A1
(43) Pub. Date: Feb. 15, 2024

(54) TOUCH DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Bo Liu, (US); Qiang Gong, (US)

(73) Assignee: WUHAN CHINA STAR OPTOELECTRONICS TECHNOLOGY CO., LTD., Wuhan, Hubei (CN)

(21) Appl. No.: 17/753,741

(22) PCT Filed: Mar. 4, 2022
(86) PCT No.: PCT/CN2022/079184

§ 371 Date: Aug. 17, 2023

(30) Foreign Application Priority Data
Feb. 14, 2022 (CN) 202210134670.7

(51) Int. Cl. G06F 3/041

(52) U.S. Cl. CPC G06F 3/0412

(57) ABSTRACT

A touch display panel and a display device are provided. The touch display panel includes transmission wirings, data lines, touch traces, and a first time-sharing transmission unit. By connecting an input terminal of the first time-sharing transmission unit to the transmission wiring, connecting a first output terminal of the first time-sharing transmission unit to the data line, and connecting a second output terminal of the first time-sharing transmission unit to the touch trace, one data line and one touch trace can be integrated into one transmission wiring to reduce occupation space of a non-display region.

### BACKGROUND OF INVENTION

### Field of Invention

The present disclosure relates to a field of display technology, and specifically to a touch display panel and a display device.

### Description of Prior Art

A touch display panel generally includes a data line DL1, a touch trace TPL1, and a touch sensor 1 as illustrated in FIG. 1. One touch trace TPL1 is electrically connected to one touch sensor 1. Wherein, both the data line DL1 and the touch trace TPL need to be respectively and independently extended to a non-display region from a display region to respectively and independently transmit corresponding data lines and touch driving signals. Therefore, the data lines DL1 and the touch traces TPL1 occupy a lot of space in the non-display region, which is not conducive to realizing a narrow bezel of the touch display panel.

It should be noted that the above description of the background of the invention is only for the purpose of facilitating clearly and completely understanding the technical solutions of the present application. Therefore, it should not be considered that the aforesaid technical solutions are known to those skilled in the art just because they appear in the background of the invention of the present.

### SUMMARY OF INVENTION

The present application provides a touch display panel and a display device to ease the technical problem that the data lines and the touch traces occupy excessive space in the non-display region.

On a first aspect, the present application provides a touch display panel, including transmission wirings, data lines, touch traces, and a first time-sharing transmission unit. An input terminal of the first time-sharing transmission unit is electrically connected to the transmission wirings. A first output terminal of the first time-sharing transmission unit is electrically connected to one of the data lines or the touch traces. A second output terminal of the first time-sharing transmission unit is electrically connected to another one of the data lines or the touch traces.

In some embodiments, the first time-sharing transmission unit includes a first transistor and a second transistor. One of a source electrode or a drain electrode of the first transistor is electrically connected to one of the transmission wirings. Another one of the source electrode or the drain electrode of the first transistor is electrically connected to one of the data lines or the touch traces. One of a source electrode or a drain electrode of the second transistor is electrically connected to one of the source electrode or the drain electrode of the first transistor. Another one of the source electrode or the drain electrode of the second transistor is electrically connected to another one of the data lines or the touch traces.

In some embodiments, the touch display panel further includes a first control wiring and a second control wiring. The first control wiring is electrically connected to one of a gate electrode of the first transistor or a gate electrode of the second transistor. The second control wiring is electrically connected to another one of the gate electrode of the first transistor or the gate electrode of the second transistor.

In some embodiments, a channel type of the first transistor is same as a channel type of the second transistor, the first control wiring is configured to transmit a first control signal, the second control wiring is configured to transmit a second control signal, and a pulse duration of the first control signal and a pulse duration of the second control signal are located in different time periods.

In some embodiments, the touch display panel further includes a third control wiring. The third control wiring is electrically connected to a gate electrode of the first transistor and a gate electrode of the second transistor.

In some embodiments, the channel type of the first transistor is one of an N-channel type or a P-channel type, the channel type of the second transistor is another one of the N-channel type or the P-channel type, the third control wiring is configured to transmit a third control signal, the third control signal has a first electric potential and a second electric potential, the first electric potential is configured to turn on one of an N-channel type transistor or a P-channel type transistor, and the second electric potential is configured to turn on another one of the N-channel type transistor or the P-channel type transistor.

In some embodiments, in one same first time-sharing transmission unit, when one of the first transistor or the second transistor is in a conductive state, another one of the first transistor or the second transistor is in a cut-off state.

In some embodiments, the touch display panel further includes a common voltage line, switch units, and touch sensors. An input terminal of the switch units is electrically connected to the common voltage line, and the switch units are simultaneously turned on or cut off with one of the first transistor or the second transistor connected to the data lines. One of the touch sensors is electrically connected to one of the touch traces and an output terminal of at least one of the switch units.

In some embodiments, the switch units include a third transistor. One of a source electrode or a drain electrode of the third transistor is electrically connected to the common voltage line. Another one of the source electrode or the drain electrode of the third transistor is electrically connected to the touch sensors. The touch display panel further a fourth control wiring. The fourth control wiring is electrically connected to a gate electrode of the third transistor. Wherein, when one of the first transistor or the second transistor connected to the data lines is turned on, the third transistor is turned simultaneously; and when another one of the first transistor or the second transistor is cut off, the third transistor is cut off.

In some embodiments, the touch display panel further includes second time-sharing transmission units. An input terminal of the second time-sharing transmission units is electrically connected to one of the transmission wirings. At least one of a first output terminal or a second output terminal of the second time-sharing transmission unit is respectively and electrically connected to one of the data lines.

In some embodiments, in an non-display region of the touch display panel, and in a first direction, at least one of the second time-sharing transmission units is between two adjacent first time-sharing transmission units.

In some embodiments, in a display region of the touch display panel, and in the first direction, at least one of the data lines is between two adjacent touch traces.

On a second aspect, the present application provides a display device, including the touch display panel of any of the aforesaid embodiments and a touch display chip. One of output terminals of the touch display chip is electrically connected to one of the transmission wirings.

In the touch display panel and the display device provided by the present application, by electrically connecting the input terminal of the first time-sharing transmission unit to the transmission wiring, by electrically connecting the first output terminal of the first time-sharing transmission unit to one of the data lines or the touch traces, and by electrically connecting the second output terminal of the first time-sharing transmission unit to another one of the data lines or the touch traces, one data line and one touch trace can be integrated or combined into one transmission wiring, which greatly saves occupation space of the non-display region and is conducive to realizing a narrow bezel.

### DESCRIPTION OF DRAWINGS

FIG. 1 is a structural schematic diagram of a touch display panel of a traditional technical solution.

FIG. 2 is a first structural schematic diagram of a touch display panel provided by one embodiment of the present application.

FIG. 3 is a second structural schematic diagram of the touch display panel provided by one embodiment of the present application.

FIG. 4 is a third structural schematic diagram of the touch display panel provided by one embodiment of the present application.

FIG. 5 is a time sequence diagram of the touch display panel illustrated in FIG. 4.

FIG. 6 is a structural schematic diagram of a display device provided by one embodiment of the present application.

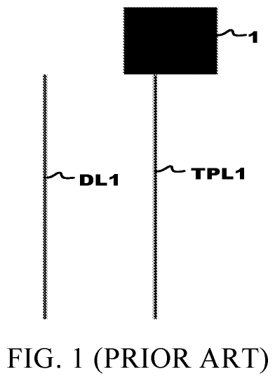

### DETAILED DESCRIPTION OF EMBODIMENTS

For making the purposes, technical solutions and effects of the present application be clearer and more definite, the present application will be further described in detail below. It should be understood that the specific embodiments described herein are merely for explaining the present disclosure and are not intended to limit the present disclosure.

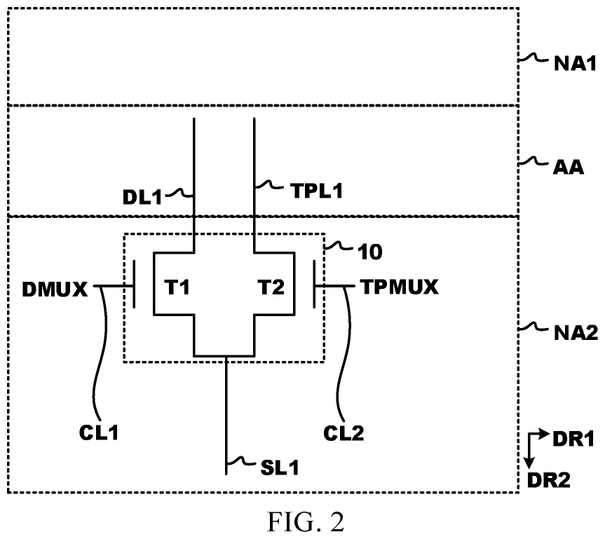

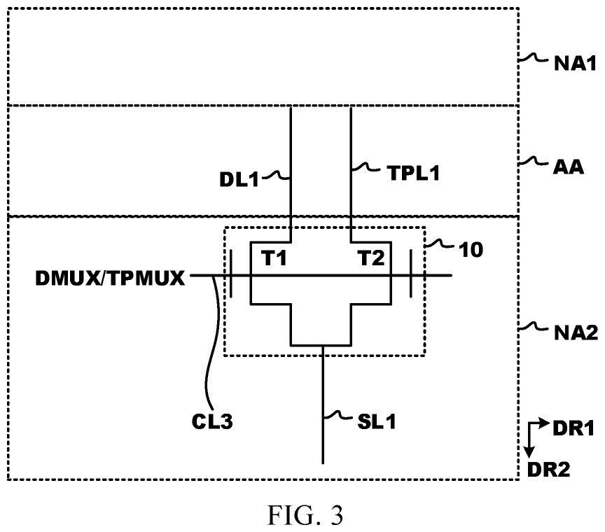

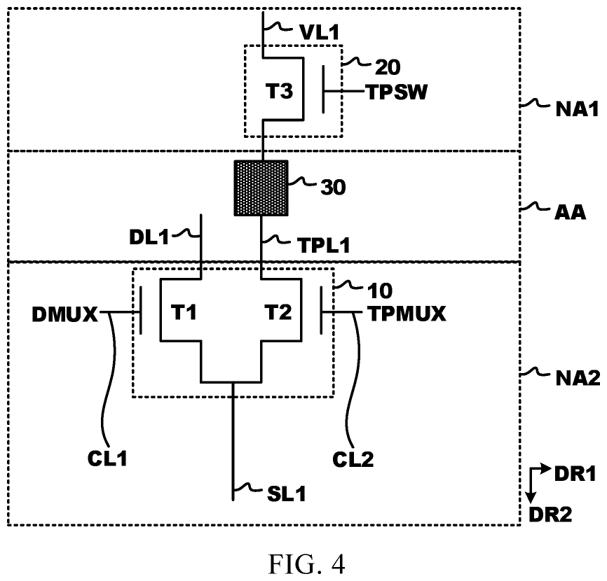

Due to a technical problem of data lines and touch traces occupying excessive space in a non-display region, this embodiment provides a touch display panel, please refer to FIG. 2 to FIG. 6. As illustrated in FIG. 2, FIG. 3, or FIG. 4, the touch display panel includes transmission wirings SL1, data lines DL1, touch traces TPL1, and a first time-sharing transmission unit 10. An input terminal of the first time-sharing transmission unit 10 is electrically connected to the transmission wirings SL1. A first output terminal of the first time-sharing transmission unit 10 is electrically connected to one of the data lines DL1 or the touch traces TPL1. A second output terminal of the first time-sharing transmission unit 10 is electrically connected to another one of the data lines DL1 or the touch traces TPL1.

It can be understood that in the touch display panel provided by this embodiment, by electrically connecting the input terminal of the first time-sharing transmission unit 10 to the transmission wiring SL1, by electrically connecting the first output terminal of the first time-sharing transmission unit 10 to one of the data lines DL1 or the touch traces TPL1, and by electrically connecting the second output terminal of the first time-sharing transmission unit 10 to another one of the data lines DL1 or the touch traces TPL1, one data line DL1 and one touch trace TPL1 can be integrated or combined into one transmission wiring SL1, which greatly saves occupation space of the non-display region and is conducive to realizing a narrow bezel.

It should be noted that in this embodiment, the first time-sharing transmission unit 10 can conduct a connection between the transmission wiring SL1 and the data line DL1 or the touch trace TPL1 in a time-sharing manner, so as to transmit a signal in the transmission wiring SL1 to the corresponding data line DL1 or touch trace TPL1 in the time sharing manner, which can respectively drive display or touch control of the touch display panel. For example, in a first time period, the first time-sharing transmission unit 10 can control the transmission wiring SL1 to connect to the data line DL1 and cut off the connection of the transmission wiring SL1 and the touch trace TPL1; and in a second time period different from the first time period, the first time-sharing transmission unit 10 can control the transmission wiring SL1 to connect to touch trace TPL1 and simultaneously cut off the connection of the transmission wiring SL1 and the data line DL1. It can be understood that this can not only reduce the non-display region, for example, space occupation of a lower bezel, but also can multiplex the signals in the transmission wiring SL1 into a data signal for driving display and a touch driving signal for driving touch control, which saves a usage number of input signals of the touch display panel.

Wherein, the data line DL1 and the touch trace can be but are limited to located in a display region of the touch display panel, and a part of the data line DL1 and a part of the touch trace TPL can be extended to the non-display region. The first time-sharing transmission unit 10 can be located in the display region of the touch display panel and/or a lower bezel region of the touch display panel. The transmission wiring SL1 is located in the lower bezel region of the touch display panel. Therefore, various inventive concepts on the basis of this embodiment can all save the non-display region of the touch display panel, and a narrow bezel can be realized.

In one of the embodiments, as illustrated in any one of FIG. 2, FIG. 3, FIG. 4, or FIG. 6, the first time-sharing transmission unit 10 can include a first transistor T1 and a second transistor T2; one of a source electrode or a drain electrode of the first transistor T1 is electrically connected to one transmission wiring SL1; another one of the source electrode or the drain electrode of the first transistor T1 is electrically connected to one of the data line DL1 or the touch trace TPL1; one of a source electrode or a drain electrode of the second transistor T2 is electrically connected to one of the source electrode or the drain electrode of the first transistor T1; and another one of the source electrode or the drain electrode of the second transistor T2 is electrically connected to another one of the data line DL1 or the touch trace TPL1.

It can be understood that, in this embodiment, when the first transistor T1 is conductive or turned on, the second transistor T2 is cut off or turned off; and when the first transistor T1 is cut off or turned off, the second transistor T2 is conductive or turned on; so as to realize time-sharing transmission of the data signals and the touch drive signals.

Wherein, when another one of the source electrode or the drain electrode of the first transistor T1 is connected to the data line DL1, another one of the source electrode or the drain electrode of the second transistor T2 is connected to the touch trace TPL1; or when another one of the source electrode or the drain electrode of the first transistor T1 is connected to the touch trace TPL1, another one of the source electrode or the drain electrode of the second transistor T2 is electrically connected to the data line DL1, which are not specifically limited herein. All of them can realize the inventive concept of the present application.

In one of the embodiments, as illustrated in FIG. 2 or FIG. 4, the touch display panel further includes a first control wiring CL1 and a second control wiring CL2, the first control wiring CL1 is electrically connected to one of a gate electrode of the first transistor T1 or a gate electrode of the second transistor T2, and the second control wiring CL2 is electrically connected to another one of the gate electrode of the first transistor T1 or the gate electrode of the second transistor T2.

It should be noted that in this embodiment, A channel type of the first transistor T1 and a channel type of the second transistor T2 are not specifically limited, and they can be independently controlled by the first control wiring CL1 or the second control wiring CL2. For example, when the first control wiring CL1 controls the first transistor T1 to turn off or to turn on, the second control wiring CL2 can control the second transistor T2 to turn on or to turn off; or when the second control wiring CL2 controls the first transistor T1 to turn off or to turn on, the first control wiring CL1 can also control the second transistor T2 to turn on or to turn off. Therefore, time-sharing transmission of the data signals and the touch drive signals can be configured more flexibly.

In one of the embodiments, a channel type of the first transistor T1 is same as a channel type of the second transistor T2, the first control wiring CL1 is configured to transmit a first control signal DMUX, the second control wiring CL2 is configured to transmit a second control signal TPMUX, and a pulse duration of the first control signal DMUX and a pulse duration of the second control signal TPMUX are located in different time periods.

It can be understood that, in this embodiment, using the first transistor T1 and the second transistor T2 with a same channel type can simplify manufacturing processes of the touch display panel. For example, a display driving circuit and a touch driving circuit can be manufactured in some same film layers in the touch display panel to form an in-cell type touch display panel, which can reduce a thickness of the touch display panel. Wherein, it should be noted that the touch display panel can be but is not limited to the in-cell type touch display panel, which can also be applicable to an on-cell type touch display panel.

It should be noted that a pulse of the first control signal DMUX can control one of the first transistor T1 or the second transistor T2 to turn on or to turn off, and a pulse of the second control signal TPMUX can control another one of the first transistor T1 or the second transistor T2 to turn on or to turn off. The pulse duration of the first control signal DMUX and the pulse duration of the second control signal TPMUX are respectively located in different time periods, which can control the first control signal T1 and the second control signal T2 to be conductive in the time-sharing manner. For example, the first transistor T1 is conductive, and the second transistor T2 is cut off; or the first transistor T1 is cut off, and the second transistor T2 is turned off.

In one of the embodiments, as illustrated in FIG. 3, the touch display panel includes a third control wiring CL3, and the third control wiring CL3 is electrically connected to a gate electrode of the first transistor T1 and a gate electrode of the second transistor T2.

It should be noted that in this embodiment, by the third control wiring CL3, the first transistor T1 and the second transistor T2 can be controlled to be in a corresponding conductive state or cut-off state respectively, which can save the number of traces in the touch display panel, and further reduces the occupation space of the lower bezel, thereby realizing a narrower bezel.

Wherein, one of the first control wiring CL1, the second control wiring CL2, or the third control wiring CL3 is located in the non-display region of the display panel, so that a penetration rate of the display panel can further improved. It should be noted that at least one of the first control wiring CL1, the second control wiring CL2, the third control wiring CL3 is not a scanning line in the prior art. In the present application, the time-sharing transmission unit is controlled by a independent control wiring instead of a scanning line, which can prevent load capacity of the scanning line from being affected.

In one of the embodiments, the channel type of the first transistor T1 is one of an N-channel type or a P-channel type, and the channel type of the second transistor T2 is another one of the N-channel type or the P-channel type. The third control wiring CL3 is configured to transmit a third control signal. The third control signal has a first electric potential and a second electric potential. The first electric potential is configured to turn on one of an N-channel type transistor or a P-channel type transistor, and the second electric potential is configured to turn on another one of the N-channel type transistor or the P-channel type transistor.

In one of the embodiments, the third control signal can be the first control signal DMUX or the second control signal TPMUX.

It should be noted that the first electric potential can be one of a high electric potential or a low electric potential, and the second electric potential can be another one of the high electric potential or the low electric potential. Wherein, the high electric potential can turn on the N-channel type transistor or can turn off the P-channel type transistor, and the low electric potential can turn off the N-channel type transistor or can turn on the P-channel type transistor. The first transistor T1 can be an oxide thin film transistor or a polycrystalline silicon thin film transistor. For example, the oxide thin film transistor can be a metal oxide thin film transistor. For example, the polycrystalline silicon thin film transistor can be a low-temperature polycrystalline-silicon thin film transistor. The second transistor T2 can also be the oxide thin film transistor or the polycrystalline silicon thin film transistor. For example, the oxide thin film transistor can be a metal oxide thin film transistor. For example, the polycrystalline silicon thin film transistor can be a low-temperature polycrystalline-silicon thin film transistor.

In one of the embodiments, in one same first time-sharing transmission unit 10, when one of the first transistor T1 or the second transistor T2 is in a conductive state, another one of the first transistor or the second transistor is in a cut-off state.

In one of the embodiments, as illustrated in FIG. 4, the touch display panel further includes a common voltage line VL1, a switch unit 20, and a touch sensor 30. An input terminal of the switch unit 20 is electrically connected to the common voltage line VL1, and the switch unit 20 is simultaneously turned on or cut off with one of the first transistor T1 or the second transistor T2 connected to the data line DL1. One touch sensor 30 is electrically connected to one touch trace TPL1 and an output terminal of at least one switch unit 20.

It should be noted that the common voltage line VL1 can be configured to transmit a common voltage signal, and the switch unit 20 is configured to transmit the common voltage signal to a corresponding pixel in a display stage of the touch display panel. Therefore, the common voltage signal required external input can be saved, a transmission path of the common voltage signal can be shortened, and voltage drop loss of the common voltage signal can also be reduced.

Wherein, the touch sensors 30 can include but are not limited to touch metal blocks, and can also include a touch drive circuit. The touch drive circuit can be electrically connected to the touch metal blocks. Wherein, these touch metal blocks or touch sensors 30 can be arranged in the display region in a matrix form. For example, the matrix can be 54 rows and 20 columns, can also 75 rows and 32 columns, or can further be 40 rows and 74 columns, etc.

In one of the embodiments, the switch unit 20 includes a third transistor T3. One of a source electrode or a drain electrode of the third transistor T3 is electrically connected to the common voltage line VL1. Another one of the source electrode or the drain electrode of the third transistor T3 is electrically connected to the touch sensor 30. The touch display panel further a fourth control wiring. The fourth control wiring is electrically connected to a gate electrode of the third transistor T3. Wherein, when one of the first transistor T1 or the second transistor T2 connected to the data lines DL1 is turned on, the third transistor T3 is turned simultaneously; and when another one of the first transistor T1 or the second transistor T2 is cut off, the third transistor T3 is cut off.

It should be noted that in this embodiment, in the display stage of the touch display panel, the third transistor T3 can be turned on, i.e., when the data line DL1 is connected to the first transistor T1, the first transistor T1 and the third transistor T3 are turned on or are conductive at a same time, and the second transistor T2 is cut off; or when the data line DL1 is connected to the second transistor T2, the second transistor T2 and the third transistor T3 are turned on or are conductive at a same time, and the first transistor T1 is cut off. In this way, in one same time period, not data signals can be transmitted, but also common voltage signals can be transmitted, which improve signal transmission efficiency, thereby can improve working efficiency of the touch display panel or a display frequency of the touch display panel.

Wherein, the third transistor T3 can be located in an upper bezel region and/or a lower bezel region of the touch display panel to increase an aperture ratio of the touch display panel.

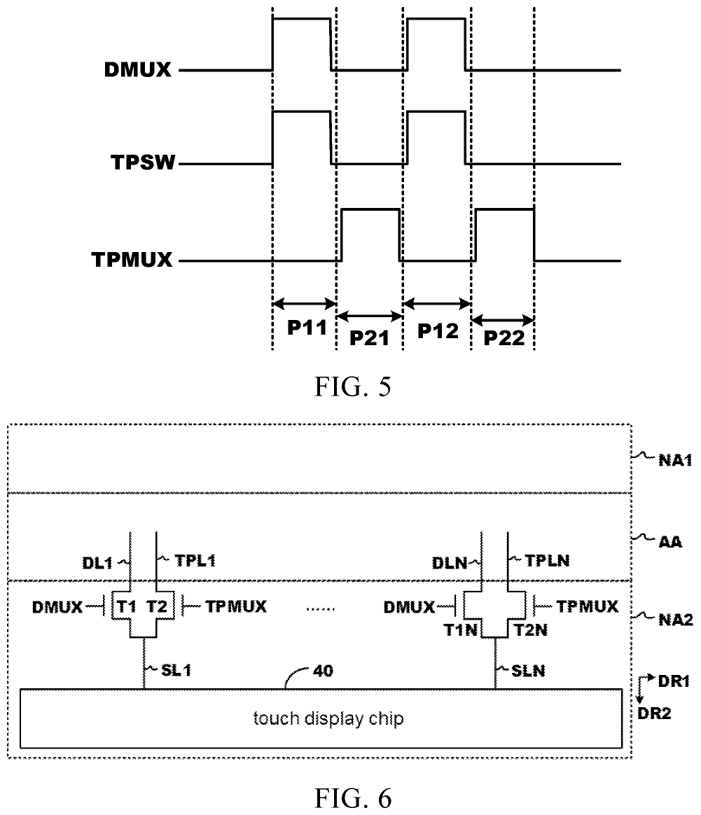

As illustrated in FIG. 5, working processes of the aforesaid touch display panel can include at least one display stage and at least one touch stage, for example, a display stage P11, display stage P12, etc., and a touch stage P21, a touch stage P22, etc.

Wherein, in the display stage P11 or the display stage P12, the first control signal DMUX transmitted in the first control wiring CL1 and a fourth control signal TPSW transmitted in the fourth control wiring are both at a high electric potential, and the first transistor T1 and the third transistor T3 are both in an conductive state. At this time, the signal in the transmission wiring SL1 can be transmitted to the data line DL1 to act as a data signal, the second control signal TPMUX transmitted in the second control wiring CL2 is at a low electric potential, and the second transistor T2 is in a cut-off state.

In the touch stage P21 or the touch stage P22, the first control signal DMUX transmitted in the first control wiring CL1 and the fourth control signal TPSW transmitted in the fourth control wiring are both at a low electric potential, the first transistor T1 and the third transistor T3 are both in the cut-off state, the second control signal TPMUX transmitted in the second control wiring CL2 is at a high electric potential, and the second transistor T2 is in the conductive state. At this time, the signal in the transmission wiring SL1 can be transmitted to the touch trace TPL1 to act as a touch driving signal.

It should be noted that in the present application, the display stage and the touch stage can be performed alternately.

In one of the embodiments, the touch display panel further includes a second time-sharing transmission unit. An input terminal of the second time-sharing transmission unit is electrically connected to one transmission wiring SL1. At least one of a first output terminal or a second output terminal of the second time-sharing transmission unit is respectively and electrically connected to one data line DL1.

It should be noted that in this embodiment, increasing the second time-sharing transmission unit can correspondingly increase the number of data lines DL1 in the display region, thereby can increase a size of the display panel or increasing a number of columns of pixels. Specifically, the second time-sharing transmission unit can include a first output terminal and/or a second output terminal. For example, when there is only a first output terminal, the first output terminal is electrically connected to one data line DL1; and when there is only a second output terminal, the second output terminal is electrically connected to one data line DL1. If the first output terminal and the second output terminal are provided at the same time, the first output terminal and the second output terminal are respectively electrically connected to one data line DL1. It can be understood that, in this way, the number of the data lines DL1 can be configured more flexibly. Wherein, a structure of the second time-sharing transmission unit can be similar to a structure of the first time-sharing transmission unit 10, only objects connected to the corresponding output ends are different.

In one of the embodiments, in a non-display region of the touch display panel, and in a first direction DR1, at least one of the second time-sharing transmission units is between two adjacent first time-sharing transmission units 10. For example, there can be two, three, four, five or six second time-sharing transmission units, etc. The layout is not only conducive to the extending paths of the touch traces and the data lines DL1 to the display area, but also It is beneficial to increase the number of data lines DL1.

It should be noted that in this embodiment, the first direction DR1 can be a horizontal direction of the display panel.

In one of the embodiments, in a display region of the touch display panel, and in the first direction DR1, at least one of the data lines DL1 is between two adjacent touch traces. For example, there can be two, three, four, five or six data lines DL1, etc., so that the number of data lines DL1 in the display region can be flexibly configured.

In one of the other embodiment, this embodiment provides a display device, which includes any of the touch display panel of at least one of the aforesaid embodiments.

It can be understood that in the display device provided by this embodiment, by electrically connecting the input terminal of the first time-sharing transmission unit 10 to the transmission wiring SL1, by electrically connecting the first output terminal of the first time-sharing transmission unit 10 to one of the data lines DL1 or the touch traces TPL1, and by electrically connecting the second output terminal of the first time-sharing transmission unit 10 to another one of the data lines DL1 or the touch traces TPL1, one data line DL1 and one touch trace TPL1 can be integrated or combined into one transmission wiring SL1, which greatly saves occupation space of the non-display region and is conducive to realizing a narrow bezel.

It should be noted that, in the display device of this embodiment, as illustrated in FIG. 6, there can be a plurality of data lines DL1, for example, data lines DL1 to DLN. There can also be a plurality of touch traces TPL1, for example, the touch trace TPL1 to the touch trace TPLN. There can also be a plurality of transmission wirings, for example, the transmission wiring SL1 to the transmission wiring SLN. Wherein, N is an integer greater than or equal to 2. However, in this embodiment, the number of data lines DL1 is not necessary to be limited to be equal to the number of touch traces TPL1, and the two can also be unequal. For example, the number of the data lines DL1 greater than the number of the touch traces TPL1, or the number of the data lines DL1 less than the number of the touch traces TPL1, all of them are applicable to the various embodiments of the present application. Similarly, the number of transmission wirings is different from the number of the data lines or touch traces, which can be configured according to actual requirements.

In one of the embodiments, the display device can further include a touch display chip 40. One of output terminals of the touch display chip 40 is electrically connected to one transmission wiring.

It should be noted that the touch display chip 40 can also be a touch display circuit or a touch display driver, which integrates a display driving function and a touch driving function, and can meet requirements of display driving and touch driving. It can be understood that the touch display chip 40 that integrates the display driving function and the touch driving function can reduce a occupation space of the touch display chip 40 compared to a structure of separately driving display and touch. Therefore, the narrow bezel can be further realized.

In one of the embodiments, as illustrated in FIG. 2, FIG. 3, FIG. 4, and FIG. 6, a first region NA1, a second region AA, and a third region NA2 are sequentially defined in the touch display panel or the display device along the second direction DR2. Wherein, the switch unit 20 and the common voltage line VL1 in FIG. 4 are located in the first region NA1. The data line DL1 to the data line DLN, the touch trace TPL1 to the data line TPLN, and the touch sensor 30 are located in the second region AA. The transmission wiring SL1 to the transmission wiring SLN, the first time-sharing transmission unit 10, the second time-sharing transmission unit, the first control wiring CL1, the second control wiring CL2, the third control wiring CL3, and the touch display chip 40 are located in the third region NA2.

It should be noted that the first region NA1 can be an upper bezel region of the touch display panel, the second region AA can be a display region of the touch display panel, and the third region NA2 can be a lower bezel region of the touch display panel.

It can be understood, that for those of ordinary skill in the art, various other corresponding changes and modifications can be made according to the technical solutions and technical ideas of the present disclosure, and all such changes and modifications are intended to fall within the scope of protection of the claims of the present disclosure.

1. A touch display panel, comprising:
transmission wirings;
data lines;
touch traces; and
a first time-sharing transmission unit, wherein an input terminal of the first time-sharing transmission unit is electrically connected to the transmission wirings, a first output terminal of the first time-sharing transmission unit is electrically connected to one of the data lines or the touch traces, and a second output terminal of the first time-sharing transmission unit is electrically connected to another one of the data lines or the touch traces.

2. The touch display panel as claimed in claim 1, wherein the first time-sharing transmission unit comprises:
a first transistor, wherein one of a source electrode or a drain electrode of the first transistor is electrically connected to one of the transmission wirings, another one of the source electrode or the drain electrode of the first transistor is electrically connected to one of the data lines or the touch traces; and
a second transistor, wherein one of a source electrode or a drain electrode of the second transistor is electrically connected to one of the source electrode or the drain electrode of the first transistor, and another one of the source electrode or the drain electrode of the second transistor is electrically connected to another one of the data lines or the touch traces.

3. The touch display panel as claimed in claim 2, wherein the touch display panel comprises:
a first control wiring, wherein the first control wiring is electrically connected to one of a gate electrode of the first transistor or a gate electrode of the second transistor; and
a second control wiring, wherein the second control wiring is electrically connected to another one of the gate electrode of the first transistor or the gate electrode of the second transistor.

4. The touch display panel as claimed in claim 3, wherein a channel type of the first transistor is same as a channel type of the second transistor, the first control wiring is configured to transmit a first control signal, the second control wiring is configured to transmit a second control signal, and a pulse duration of the first control signal and a pulse duration of the second control signal are located in different time periods.

5. The touch display panel as claimed in claim 2, wherein the touch display panel comprises a third control wiring, the third control wiring is electrically connected to a gate electrode of the first transistor and a gate electrode of the second transistor.

6. The touch display panel as claimed in claim 5, wherein the channel type of the first transistor is one of an N-channel type or a P-channel type, the channel type of the second transistor is another one of the N-channel type or the P-channel type, the third control wiring is configured to transmit a third control signal, the third control signal has a first electric potential and a second electric potential, the first electric potential is configured to turn on one of an N-channel type transistor or a P-channel type transistor, and the second electric potential is configured to turn on another one of the N-channel type transistor or the P-channel type transistor.

7. The touch display panel as claimed in claim 3, wherein in the first time-sharing transmission unit, when one of the first transistor or the second transistor is in a conductive state, another one of the first transistor or the second transistor is in a cut-off state.

8. The touch display panel as claimed in claim 2, wherein the touch display panel comprises:
a common voltage line;
switch units, wherein an input terminal of the switch units is electrically connected to the common voltage line, and
the switch units are simultaneously turned on or cut off with one of the first transistor or the second transistor connected to the data lines; and
touch sensors, wherein one of the touch sensors is electrically connected to one of the touch traces and an output terminal of at least one of the switch units.

9. The touch display panel as claimed in claim 8, wherein the switch units comprise a third transistor, one of a source electrode or a drain electrode of the third transistor is electrically connected to the common voltage line, another one of the source electrode or the drain electrode of the third transistor is electrically connected to the touch sensors,
the touch display panel comprises a fourth control wiring, and the fourth control wiring is electrically connected to a gate electrode of the third transistor; and
wherein when one of the first transistor or the second transistor connected to the data lines is turned on, the third transistor is turned simultaneously; and when another one of the first transistor or the second transistor is cut off, the third transistor is cut off.

10. The touch display panel as claimed in claim 1, wherein the touch display panel comprises second time-sharing transmission units, an input terminal of the second time-sharing transmission units is electrically connected to one of the transmission wirings, and at least one of a first output terminal or a second output terminal of the second time-sharing transmission unit is respectively and electrically connected to one of the data lines.

11. The touch display panel as claimed in claim 10, wherein in an non-display region of the touch display panel, and in a first direction, at least one of the second time-sharing transmission units is between two adjacent first time-sharing transmission units.

12. The touch display panel as claimed in claim 11, wherein in a display region of the touch display panel, and in the first direction, at least one of the data lines is between two adjacent touch traces.

13. A display device, comprising:
the touch display device as claimed in claim 1; and
a touch display chip, wherein one of output terminals of the touch display chip is electrically connected to one of the transmission wirings.

14. The display device as claimed in claim 13, wherein the first time-sharing transmission unit comprises:
a first transistor, wherein one of a source electrode or a drain electrode of the first transistor is electrically connected to one of the transmission wirings, another one of the source electrode or the drain electrode of the first transistor is electrically connected to one of the data lines or the touch traces; and
a second transistor, wherein one of a source electrode or a drain electrode of the second transistor is electrically connected to one of the source electrode or the drain electrode of the first transistor, and another one of the source electrode or the drain electrode of the second transistor is electrically connected to another one of the data lines or the touch traces.

15. The display device as claimed in claim 14, wherein the touch display panel comprises:
a first control wiring, wherein the first control wiring is electrically connected to one of a gate electrode of the first transistor or a gate electrode of the second transistor; and
a second control wiring, wherein the second control wiring is electrically connected to another one of the gate electrode of the first transistor or the gate electrode of the second transistor.

16. The display device as claimed in claim 15, wherein a channel type of the first transistor is same as a channel type of the second transistor, the first control wiring is configured to transmit a first control signal, the second control wiring is configured to transmit a second control signal, and a pulse duration of the first control signal and a pulse duration of the second control signal are located in different time periods.

17. The display device as claimed in claim 14, wherein the touch display panel comprises a third control wiring, the third control wiring is electrically connected to a gate electrode of the first transistor and a gate electrode of the second transistor.

18. The display device as claimed in claim 17, wherein the channel type of the first transistor is one of an N-channel type or a P-channel type, the channel type of the second transistor is another one of the N-channel type or the P-channel type, the third control wiring is configured to transmit a third control signal, the third control signal has a first electric potential and a second electric potential, the first electric potential is configured to turn on one of an N-channel type transistor or a P-channel type transistor, and the second electric potential is configured to turn on another one of the N-channel type transistor or the P-channel type transistor.

19. The display device as claimed in claim 15, wherein in the first time-sharing transmission unit, when one of the first transistor or the second transistor is in a conductive state, another one of the first transistor or the second transistor is in a cut-off state.

20. The display device as claimed in claim 14, wherein the touch display panel comprises:
a common voltage line;
switch units, wherein an input terminal of the switch units is electrically connected to the common voltage line, and
the switch units are simultaneously turned on or cut off with one of the first transistor or the second transistor connected to the data lines; and
touch sensors, wherein one of the touch sensors is electrically connected to one of the touch traces and an output terminal of at least one of the switch units.
